(19) United States
(12) Patent Application Publication
(10) Pub. No.: US 2003/0127751 A1
(43) Pub. Date: Jul. 10, 2003

(54) Alignment mark structure

(75) Inventors: Tetsuya Yamada, Tokyo (JP); Atsushi Ueno, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/202,656

(22) Filed: Jul. 25, 2002

(30) Foreign Application Priority Data
Jan. 9, 2002 (JP) 2002-002280

(51) Int. Cl. H01L 23/544

(52) U.S. Cl. 257/797

(57) ABSTRACT

An alignment mark structure according to the present invention includes alignment marks (8) and underlying layers (5) arranged under the alignment marks (8). The underlying layers (5) each form a line for defining a pattern. A metal diffusion preventing and etching stopper layer (6) is interposed between the underlying layers (5) and the alignment marks (8). As the underlying layers (5) each form a line, dishing therein can be suppressed even when the underlying layers (5) are formed through a damascene process. As a result, there occurs no difference in level between the alignment marks (8) that may result in deterioration in alignment accuracy. Further, due to existence of the metal diffusion preventing and etching stopper layer (6), metallic material for forming the underlying layers (5) can be prevented from diffusing resulting from a thermal processing, for example.

### BACKGROUND OF THE INVENTION

1. Field of the Invention

The present invention relates to alignment in lithography as one of the steps in a method of manufacturing a semiconductor device. More particularly, it relates to an alignment mark structure in a semiconductor device having a multilayer interconnection structure with a damascene structure.

2. Description of the Background Art

In background-art manufacturing steps of a semiconductor device repeating transfer several times using a mask, an alignment mark has been utilized. According to alignment using an alignment mark, relative positions of an existing pattern transferred to a semiconductor substrate in a previous step and a pattern to be transferred in a next step (mask pattern) are optimally adjusted.

FIGS. 16A through 16C illustrate an alignment mark structure in a background-art semiconductor device having a multilayer interconnection structure. FIG. 16A is a top plan view illustrating a portion of the semiconductor device including alignment marks, FIG. 16B is a sectional view taken along a line M1-N1 in FIG. 16A, and FIG. 16C is a sectional view taken along a line P1-Q1 in FIG. 16A. A reference numeral 101 designates a silicon substrate, numerals 102, 103, 104 and 106 each designate an interlayer insulating film, and a numeral 105 designates alignment marks. Further, a reference numeral 107 designates a resist serving as a mask for selectively etching the interlayer insulating film 106.

When a multilayer interconnection structure is to be formed, the alignment marks 105 are formed apart from the silicon substrate 101 as illustrated in FIGS. 16A through 16C. Due to this, focusing in the step of detecting alignment pattern for alignment measurement cannot be performed with stability, causing deterioration in alignment accuracy in alignment measurement. As a result, in a lithography step relative to the alignment marks 105 using the resist 107, there occurs deterioration in alignment accuracy of a transfer pattern.

FIGS. 17A through 17C illustrate a suggested alignment mark structure in a background-art semiconductor device as a countermeasure against this problem. FIG. 17A is a top plan view illustrating a portion of the semiconductor device including alignment marks, FIG. 17B is a sectional view taken along a line M2-N2 in FIG. 17A, and FIG. 17C is a sectional view taken along a line P2-Q2 in FIG. 17A. In FIGS. 17A through 17C, elements serving the same functions as those of the elements in FIGS. 16A through 16C are designated by the same reference numerals. As illustrated in FIGS. 17A through 17C, the suggested structure includes an underlying layer 110 provided under the alignment marks 105. The underlying layer 110 includes a metal interconnect material and serves as a reference plane for focusing, thus allowing improvement in stability of focusing.

With a tendency in recent years toward higher level of integration, even in a multilayer interconnection structure, interconnect lines are required to be reduced in dimension with lessened spaces therebetween. However, forming a resist pattern on a metal film utilizing a transfer technique causes halation due to high reflectivity of the metal film, leading to difficulty in forming interconnect line. In view of this, a damascene process has been utilized for realizing reduction in dimension of an interconnect line.

According to the damascene process, a contact hole and an interconnect trench pattern are defined in an insulating film. Next, the hole and the trench pattern are filled with their respective materials entirely deposited therein. Thereafter the excess parts of these materials other than those for filling the hole and the trench pattern is removed by CMP (chemical mechanical polishing), thus forming the contact and interconnect line.

With reference to FIGS. 18A through 18D, the steps of forming a buried interconnect line utilizing the damascene process will be described. First, an interlayer insulating film 121 is provided on a silicon substrate 120. The interlayer insulating film 121 holds a resist 122 provided thereon having an opening to serve as an interconnect line forming region (FIG. 18A). Next, using the resist 122 as a mask, a trench 123 is defined in the interlayer insulating film 121 to serve as an interconnect pattern. Thereafter the resist 122 is removed (FIG. 18B). After this, an interconnect material 124 is deposited on the interlayer insulating film 121 including the interconnect pattern 123 formed therein (FIG. 18C). Finally, an excess part of the interconnect material 124 other than the part for filling the interconnect pattern 123 is removed by CMP, thus forming a buried interconnect line 125 (FIG. 18D).

Utilizing the damascene process, a structure including a contact 132 and an interconnect line 133 formed in an interlayer insulating film 131 on an underlying interconnect layer 130 is provided as illustrated in an exemplary view of FIG. 19. FIGS. 20A through 20D illustrate the steps of forming such structure. Following the same steps as in FIGS. 18A through 18D, an interlayer insulating film 131a is provided on the underlying interconnect layer 130 and the contact 132 is defined (FIG. 20A). Next, an interlayer insulating film 131b is provided on the interlayer insulating film 131a including the contact 132 formed therein (FIG. 20B). Thereafter following the same steps as in FIGS. 18A through 18D, a trench 133a is defined for forming the interconnect line 133 (FIG. 20C). The interconnect line 133 filling the trench 133a is formed as illustrated in FIG. 20D. That is, performing normal damascene process twice, the structure illustrated in FIG. 19 is provided including the contact 132 and the interconnect line 133 formed in the interlayer insulating film 131 (in the interlayer insulating films 131a and 131b, respectively).

The damascene process for forming the structure exemplified in FIG. 19 includes a dual damascene process. The dual damascene process further includes a hole first process and a trench first process. FIGS. 21A through 21C illustrate the steps of forming the structure in FIG. 19 following the hole first process. First, as illustrated in FIG. 21A, the interlayer insulating film 131 is provided on the underlying interconnect layer 130 and a hole pattern 132b for forming the contact 132 is defined in the interlayer insulating film 131. Next, a trench (interconnect pattern) 133b is defined for forming the interconnect line 133 (FIG. 21B). Then an interconnect material is deposited on the interlayer insulating film 131. Thereafter an excess part of the material other than the part for filling the hole pattern 132b and the interconnect pattern 133b is removed by CMP, thus forming the contact 132 and the interconnect line 133 (FIG. 21C). Namely, according to the hole first process, a hole pattern is defined prior to an interconnect pattern.

FIGS. 22A through 22C illustrate the steps of forming the structure in FIG. 19 following the trench first process. First, as illustrated in FIG. 22A, the interlayer insulating film 131 is provided on the underlying interconnect layer 130 and a trench (interconnect pattern) 133c for forming the interconnect line 133 is defined. Next, a hole pattern 132c is defined for forming the contact 132 (FIG. 22B). Then an interconnect material is deposited on the interlayer insulating film 131. Thereafter an excess part of the material other than the part for filling the hole pattern 132c and the interconnect pattern 133c is removed by CMP, thus forming the contact 132 and the interconnect line 133 (FIG. 22C). Namely, according to the trench first process, an interconnect pattern is defined prior to a hole pattern.

According to the dual damascene process, a hole and an interconnect line are simultaneously buried as described. In contrast to the dual damascene process, the process illustrated in FIGS. 20A through 20D is called as a single damascene process.

FIGS. 23A, 23B and FIGS. 24A, 24B illustrate the problems occurring in the alignment mark structure in the background art. In these figures, elements serving the same functions as those of the elements in FIGS. 17A through 17C are designated by the same reference numerals and the detailed description thereof is omitted here. FIGS. 23A and 24A are top plan views. FIGS. 23B and 24B are sectional views taken along a line R1-S1 in FIG. 23A and taken along a line R2-S2 in FIG. 24A, respectively.

The damascene processes described so far for forming a multilayer interconnection structure necessitates CMP even when an underlying layer to serve as a reference plane for focusing for alignment is formed, causing dishing in the underlying layer 110 as illustrated in FIG. 23B. As a result, there occurs difference in level between alignment marks to be formed on the underlying layer 110, causing deterioration in focusing accuracy in the process of reading alignment marks. Dishing may occur to an excessive degree in some cases, leading to the structure in FIG. 24B. As illustrated in FIG. 24B, a central portion of the underlying layer 110 is completely removed and the interlayer insulating film 102 under the underlying layer 110 is exposed, causing deterioration in alignment accuracy. Due to this, in a semiconductor device having a multilayer interconnection structure formed by the damascene process, it has been difficult to form an underlying layer allowing improvement in focusing accuracy to a sufficient extent.

### SUMMARY OF THE INVENTION

In a semiconductor device having a multilayer interconnection structure formed through the damascene process, it is an object of the present invention to provide an alignment mark structure allowing improvement in accuracy in the process of reading alignment mark and improvement in alignment accuracy.

According to the present invention, the alignment mark structure has alignment marks and underlying layers including metallic material and being arranged under the alignment marks. The underlying layer each form a line for defining a pattern. The alignment mark structure further has a metal diffusion preventing and etching stopper layer directly on the underlying layers.

In the manufacturing steps of the alignment mark structure, dishing in the underlying layers is suppressed and there occurs no difference in level between the alignment marks. As a result, deterioration in focusing accuracy in the process of reading alignment marks can be reduced. Further, due to existence of the metal diffusion preventing and etching stopper layer, the metallic material for forming the underlying layers can be prevented from diffusing resulting from a thermal processing, for example, to be performed after formation of the underlying layers. Still further, regardless of whether a semiconductor device is to be formed through the dual damascene process or single damascene process, no change in process and no increase in number of steps are required in the background-art method of manufacturing the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A through 1C illustrate an alignment mark structure according to a first preferred embodiment of the present invention;

FIG. 2, FIGS. 3A through 3C, FIGS. 4A through 4C, FIG. 5, and FIGS. 6A through 6C illustrate the steps of forming the alignment mark structure according to the first preferred embodiment of the present invention;

FIG. 7 illustrates a waveform of a signal detected by a detector in the process of reading alignment marks from the alignment mark structure according to the first preferred embodiment of the present invention;

FIG. 8, FIGS. 9A through 9C, FIG. 10 and FIGS. 11A through 11C illustrate modifications of the alignment mark structure according to the first preferred embodiment of the present invention;

FIGS. 12A through 12C illustrate an alignment mark structure according to a second preferred embodiment of the present invention;

FIG. 13 illustrates a waveform of a signal detected by a detector in the process of reading alignment marks from the alignment mark structure according to the second preferred embodiment of the present invention;

FIGS. 14A through 14C illustrate an alignment mark structure according to a third preferred embodiment of the present invention;

FIG. 15 illustrates a waveform of a signal detected by a detector in the process of reading alignment marks from the alignment mark structure according to the third preferred embodiment of the present invention;

FIGS. 16A through 16C and FIGS. 17A through 17C respectively illustrate alignment mark structures in the background art;

FIGS. 18A through 18D illustrate the steps of forming a buried interconnect line following the damascene process;

FIG. 19 illustrates a contact and an interconnect line formed by the damascene process;

FIGS. 20A through 20D illustrate the steps of forming a contact and an interconnect line following the single damascene process;

FIGS. 21A through 21C illustrate the steps of forming a contact and an interconnect line following the hole first process;

FIGS. 22A through 22C illustrate the steps of forming a contact and an interconnect line following the trench first process; and

FIGS. 23A, 23B and FIGS. 24A, 24B illustrate the problems occurring in the alignment mark structure in the background art.

### DESCRIPTION OF THE PREFERRED EMBODIMENTS

<First Preferred Embodiment>

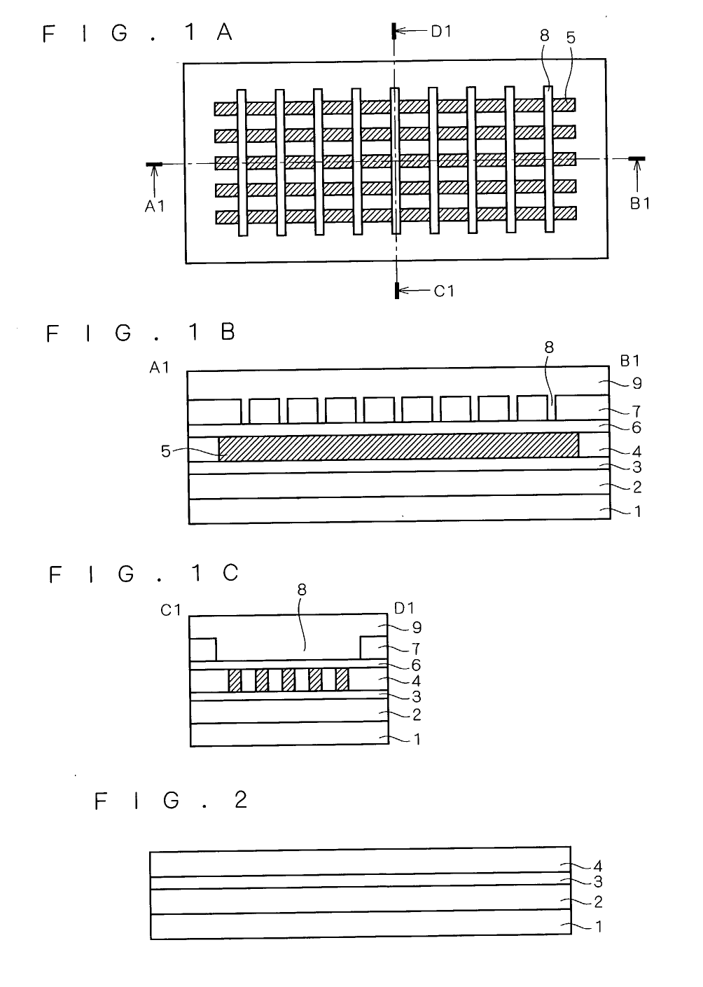

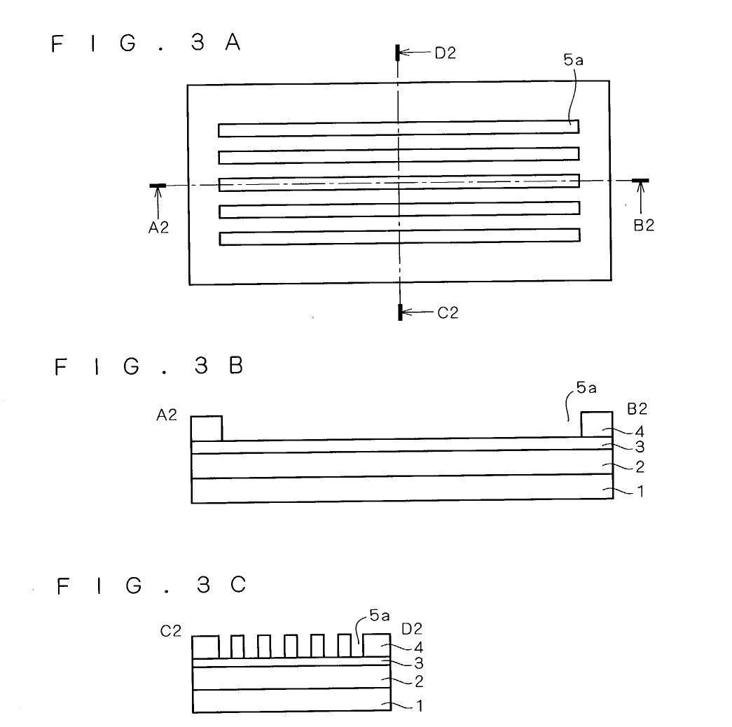

FIGS. 1A through 1C illustrate an alignment mark structure in a semiconductor device according to the first preferred embodiment of the present invention. FIG. 1A is a top plan view illustrating a portion of the semiconductor device including alignment marks, FIG. 1B is a sectional view taken along a line A1-B1 in FIG. 1A, and FIG. 1C is a sectional view taken along a line C1-D1 in FIG. 1A. A reference numeral 1 designates a silicon substrate and numerals 2, 4, 7 each designate an interlayer insulating film. Further, reference numerals 3, 6 each designate a metal diffusion preventing and etching stopper layer, and a numeral 5 designates underlying layers each serving as a reference plane for focusing. Still further, reference numerals 8 and 9 designate alignment marks and a resist, respectively.

According to the alignment mark structure of the first preferred embodiment, the alignment marks 8 each defining an opening are arranged in parallel and the underlying layers 5 provided under the alignment marks 8 form parallel lines as illustrated in FIGS. 1A through 1C. That is, both the alignment marks 8 and the underlying layers 5 follow an L/S (line and space) pattern. Each alignment mark 8 defining an opening and each underlying layer 5 forming a line are orthogonal to each other in extending direction. Further, the metal diffusion preventing and etching stopper layer 6 (hereinafter may be referred to simply as “stopper layer 6” for convenience of description) is interposed between the underlying layers 5 and the alignment marks 8.

The steps of forming the alignment mark structure as illustrated in FIGS. 1A through 1C according to the first preferred embodiment will be described with reference to FIG. 2, FIGS. 3A through 3C, FIGS. 4A through 4C, FIG. 5 and FIGS. 6A through 6C. In these figures, elements corresponding to those in FIGS. 1A through 1C are designated by the same reference numerals.

First, a semiconductor element such as transistor is provided on the silicon substrate 1 and thereafter, the interlayer insulating film 2 is provided. Provided in the subsequent step are the metal diffusion preventing and etching stopper layer 3 and the interlayer insulating film 4 on the interlayer insulating film as illustrated in FIG. 2. The metal diffusion preventing and etching stopper layer may include SiN or SiC. The interlayer insulating film 2 may be an insulating film or low dielectric constant film including SiO₂, SiOF, SiC, α-C (amorphous carbon), SiLK™ and SiOC, for example.

Following the damascene process, trenches for forming a first interconnect line and holes for forming a first contact (not illustrated) are defined in the interlayer insulating film 4. In this step, as illustrated in FIGS. 3A through 3C, openings 5a for forming the in-line underlying layers 5 are defined in the interlayer insulating film 4 at a portion for holding alignment marks to be formed thereover. FIG. 3A is a top plan view illustrating a portion of the semiconductor device including to-be-formed alignment marks, FIG. 3B is a sectional view taken along a line A2-B2 in FIG. 3A, and FIG. 3C is a sectional view taken along a line C2-D2 in FIG. 3A.

Next, the trenches for the first interconnect line and the holes for the first contact, and the openings 5a are filled with barrier metal such as Ti, TiN, Ta, Tan, TiSiN, TiSi, TiW and TiWN, thus forming a conductive metal diffusion preventing film to grow to a small thickness. Following the damascene process, an interconnect material is thereafter deposited on the conductive metal diffusion preventing film and an excess part of the material is removed by CMP, thus forming the first interconnect line, the first contact and the in-line underlying layers 5 in the interlayer insulating film 4 including metallic material as illustrated in Figs. A through C. FIG. 4A is a top plan view, FIG. 4B is a sectional view taken along a line A3-B3 in FIG. 4A, and FIG. 4C is a sectional view taken along a line C3-D3 in FIG. 4A. The underlying layers 5 follow an in-line pattern and therefore, there occurs no dishing in the underlying layers 5 during CMP.

In the subsequent step, the metal diffusion preventing and etching stopper layer 6 is provided on the interlayer insulating film 4 (namely, directly on the underlying layers 5). The stopper layer 6 holds the interlayer insulating film 7 provided thereon as illustrated in FIG. 5. Due to existence of the stopper layer 6, the metallic interconnect material for forming the underlying layers 5, the first interconnect line and the first contact, for example, can be prevented from diffusing resulting from the subsequent steps such as a thermal processing.

Thereafter, following the damascene process, trenches for forming a second interconnect line and holes for forming a second contact (not illustrated) are defined in the interlayer insulating film 7. In this step, openings for forming the alignment marks 8 are defined in the interlayer insulating film 7.

In the following description, the second interconnect line and the second contact are to be formed in the interlayer insulating film 7 through the hole first process of the dual damascene. First, in the step of defining the holes for forming the second contact through the hole first process, the in-line alignment marks 8 each reaching the stopper layer 6 are formed in the interlayer insulating film 7 as illustrated in FIGS. 6A through 6C. FIG. 6A is a top plan view, FIG. 6B is a sectional view taken along a line A4-B4 in FIG. 6A, and FIG. 6C is a sectional view taken along a line C4-D4 in FIG. 6A. Due to existence of the stopper layer 6, the alignment marks 8 can be prevented from penetrating the interlayer insulating film 4 and the underlying layers 5 resulting from excessive etching.

Thereafter the resist 9, serving as a mask in the step of defining the trench for forming the second interconnect line through the hole first process, is provided on the interlayer insulating film 7, thereby reaching the structure illustrated in FIG. 1. According to the position of the alignment mark 8 detected by an alignment mark detector, alignment of a mask pattern for the second interconnect line is performed in a subsequent lithography step using the resist 9. That is, according to the hole first process, the alignment mark to be used for alignment of the mask pattern for the second interconnect line is an opening defined in the interlayer insulating film 7.

As described, the underlying layers 5 follow an in-line pattern. Therefore, dishing resulting from CMP is suppressed, thus causing no difference in level between alignment marks. As a result, deterioration in focusing accuracy in the process of reading alignment marks can be reduced. Further, the underlying layers 5 follow an L/S pattern. Therefore, contrast exhibited in a portion including alignment marks in an image processing for reading alignment marks can be improved, thus contributing to improvement in alignment accuracy.

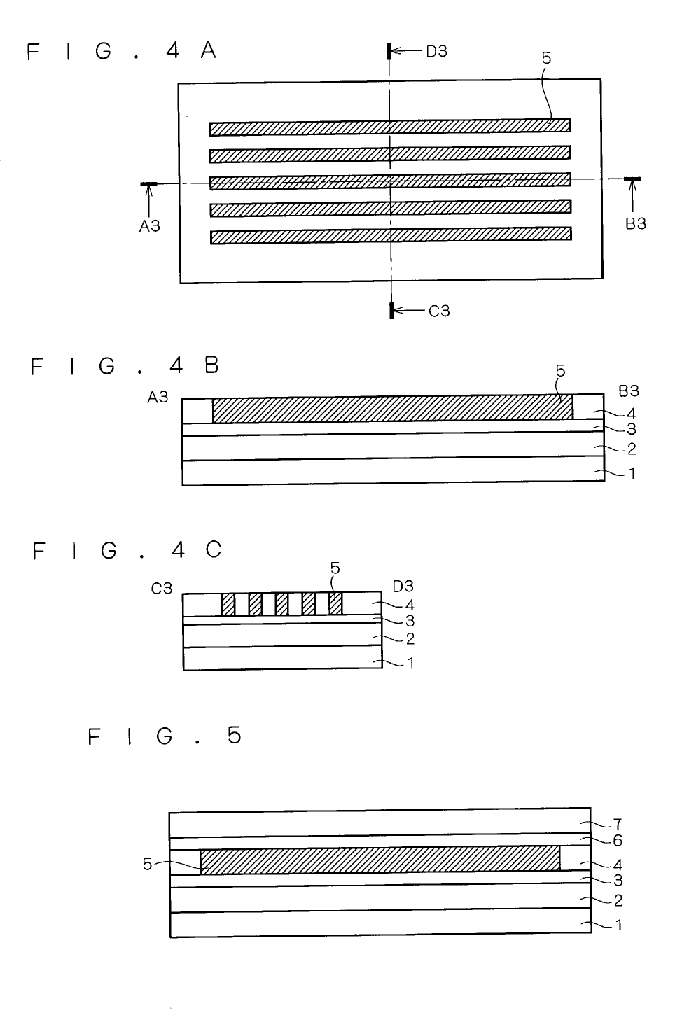

FIG. 7 shows an exemplary relation between a waveform of a signal detected by a detector and positions of alignment marks in the process of reading alignment marks. When alignment marks are to be detected by means of image recognition, for example, the number of pixels existing along an extending direction of an opening of an alignment mark and having color and brightness indicating the alignment mark is utilized, thus forming a waveform of a signal. It is seen from FIG. 7 that the wave has peaks at points of existence of the alignment marks.

Focusing accuracy is improved as a line width of each of the underlying layers 5 following a line pattern (L/S pattern) increases. However, increase in line width raises the amount of dishing, causing deterioration in stability of focusing. In contrast, focusing accuracy is deteriorated with increase to an excessive degree in space between the lines of the underlying layers 5. On the other hand, reduction in space therebetween to an excessive degree produces little effect on improvement in contrast. In view of this, line widths of the underlying layers and the space therebetween should be optimally adjusted according to a trade-off between focusing accuracy and contrast.

In the foregoing description, the second interconnect line and the second contact have been formed in the interlayer insulating film 7 following the hole first process of the dual damascene. However, applicability of the present invention should not be limited to this. If the trench first process is alternatively utilized, for example, the alignment marks 8 may be formed in the step of defining the trenches for forming the second interconnect line that is to be performed prior to the step of defining the holes for forming the second contact. In this case, the alignment marks 8 formed in the interlayer insulating film 7 do not reach the stopper 6 as illustrated in FIG. 8. However, the same effect as obtained by the hole first process can be certainly achieved.

Still alternatively, the second interconnect line and the second contact may be formed through the single damascene process. In this case, the alignment marks 8 are formed in the interlayer insulating film 7 in the step of defining the holes for forming the second contact. According to the single damascene process, the contact hole is filled with an interconnect material immediately after formation of the alignment marks 8 and therefore, the alignment marks 8 are also filled with the interconnect material. That is, according to the single damascene process, the alignment mark 8 to be used for alignment of the mask pattern for the second interconnect line in a subsequent step is the interconnect material for filling the opening defined in the interlayer insulating film 7. Next, as illustrated in FIGS. 9A through 9C, a metal diffusion preventing and etching stopper layer 10, an interlayer insulating film 11 for forming the second interconnect line and a resist 12 are provided. According to the position of the alignment mark 8 detected by the alignment mark detector, alignment of the mask pattern for the second interconnect line is performed in a subsequent lithography step using the resist 12. FIG. 9A is a top plan view, FIG. 9B is a sectional view taken along a line A5-B5 in FIG. 9A, and FIG. 9C is a sectional view taken along a line C5-D5 in FIG. 9A.

As described, the openings of the underlying layers 5 are defined in the interlayer insulating film in the step of defining the trenches for forming the first interconnect line and the holes for forming the first contact. Therefore, if the first interconnect line is to be formed following the alternative process such as dual damascene while defining the openings of the underlying layers 5, the underlying layers 5 do not reach the stopper layer 3 as illustrated in FIG. 10. However, the same effect as obtained by the underlying layers reaching the stopper layer 3 can be certainly achieved.

According to the exemplary structure given above in which the openings of the underlying layers 5 are defined directly below the interlayer insulating film 7 for forming the alignment marks 8, alignment accuracy and focusing accuracy realized in the first preferred embodiment reach their highest levels. Alternatively, the underlying layers 5 may be arranged apart from the interlayer insulating film 7 for forming the alignment marks 8 as illustrated in FIGS. 11A through 11C. FIG. 11A is a top plan view, FIG. 11B is a sectional view taken along a line A6-B6 in FIG. 11A, and FIG. 11C is a sectional view taken along a line C6-D6 in FIG. 11A. In FIGS. 11A through 11C, a reference numeral 13 designates an interlayer insulating film and a numeral 14 designates a stopper layer. This structure may exhibit deterioration in focusing accuracy to some extent as compared with the structure including the underlying layers 5 provided directly below the interlayer insulating film 7. However, alignment accuracy can be still improved to the same extent.

According to the alignment mark structure of the first preferred embodiment, regardless of whether a semiconductor device having a multilayer interconnection structure is to be formed through the dual damascene process or single damascene process of the background-art dual damascene, alignment accuracy and focusing accuracy can be improved while requiring no change in process and no increase in number of the steps in a method of manufacturing the semiconductor device.

<Second Preferred Embodiment>

According to the first preferred embodiment, the alignment marks 8 defining openings arranged in parallel and the underlying layers 5 forming parallel lines are orthogonal to each other in extending direction. However, applicability of the present invention should not be limited to this. Relation between the openings of the alignment marks 8 and the lines of the underlying layers 5 may be arbitrarily established in extending direction.

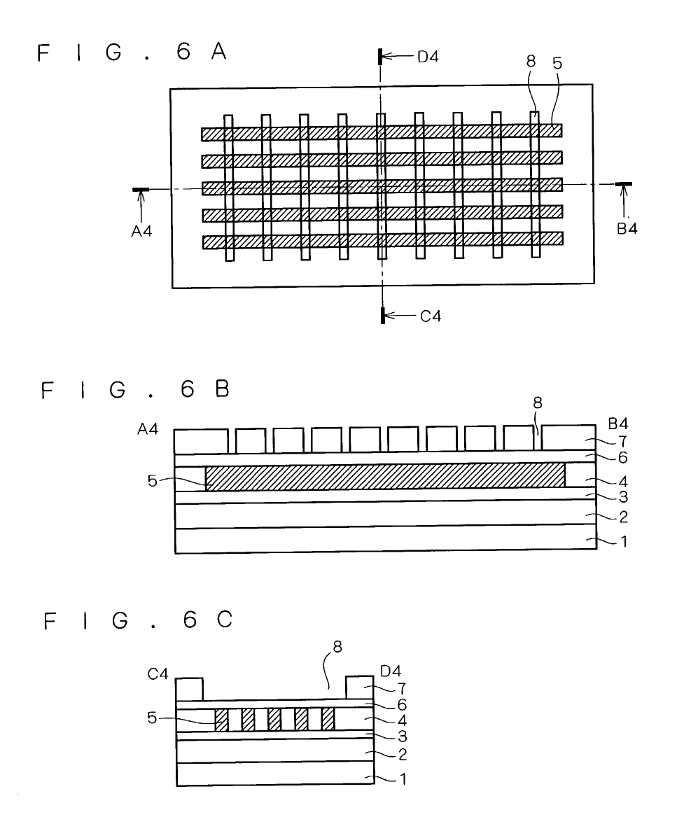

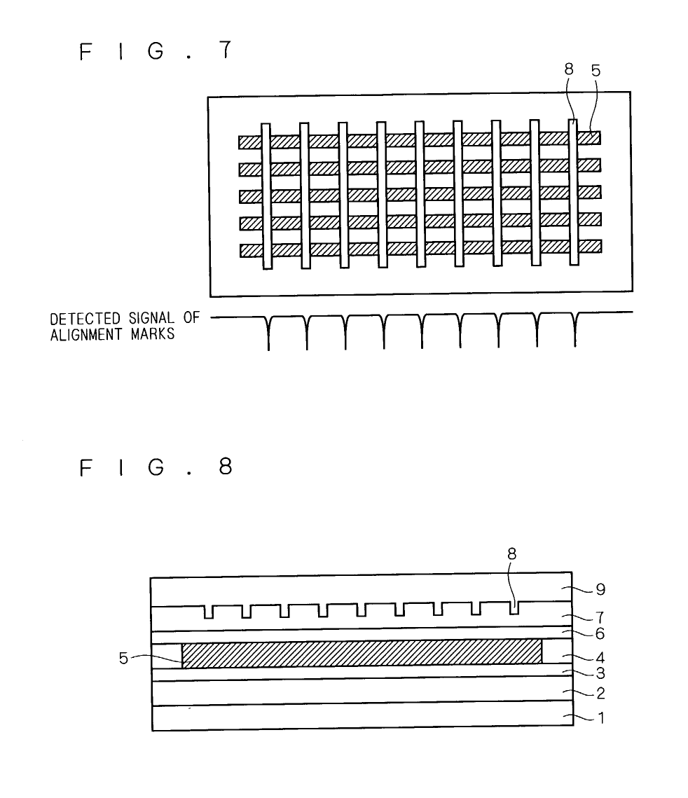

According to the second preferred embodiment of the present invention, the lines of the underlying layers 5 and the openings of the alignment marks 8 extend in parallel with each other. FIGS. 12A through 12C illustrate an alignment mark structure according to the second preferred embodiment. FIG. 12A is a top plan view, FIG. 12B is a sectional view taken along a line E-F in FIG. 12A, and FIG. 12C is a sectional view taken along a line G-H in FIG. 12A. In FIGS. 12A through 12C, elements serving the same functions as those of the elements in FIGS. 1A through 1C are designated by the same reference numerals and the detailed description thereof is omitted here. The alignment mark structure according to the second preferred embodiment certainly achieves the same effect as obtained in the alignment mark structure according to the first preferred embodiment.

As seen from FIGS. 12A through 12C, in the alignment mark structure according to the second preferred embodiment, the parallel lines of the underlying layers 5 follow the same periodicity as that of the parallel openings of the alignment marks 8.

FIG. 13 shows a relation between a waveform of a signal detected by an alignment mark detector and positions of alignment marks in the process of reading alignment marks from the alignment mark structure illustrated in FIGS. 12A through 12C. As seen from FIG. 13, the wave of the detected signal defined by the alignment marks according to the second preferred embodiment has peaks 20 at points of existence of the alignment marks 8. The wave further has peaks 21 each being at a lower amplitude at edge portions of the underlying layers 5. Due to this, it is required to extract the peaks defined only by the alignment marks 8 through signal analysis. More particularly, the peaks defined by the alignment mark 8 and the edge portion of the underlying layer 5 are detected in amplitude. When the peak has an amplitude higher than a predetermined threshold value, it is determined as the one defined by the alignment mark 8. It is thus allowed to extract the peaks defined only by the alignment marks 8.

According to the exemplary structure in FIGS. 12A through 12C, the alignment marks 8 are formed in the step of forming a hole through the hole first process. Alternatively, the second preferred embodiment is certainly applicable to the trench first process and the single damascene process.

<Third Preferred Embodiment>

According to the second preferred embodiment, the lines of the underlying layers 5 and the openings of the alignment marks 8 extend in parallel with each other. Further, the parallel lines of the underlying layers 5 follow the same periodicity as that of the parallel openings of the alignment marks 8.

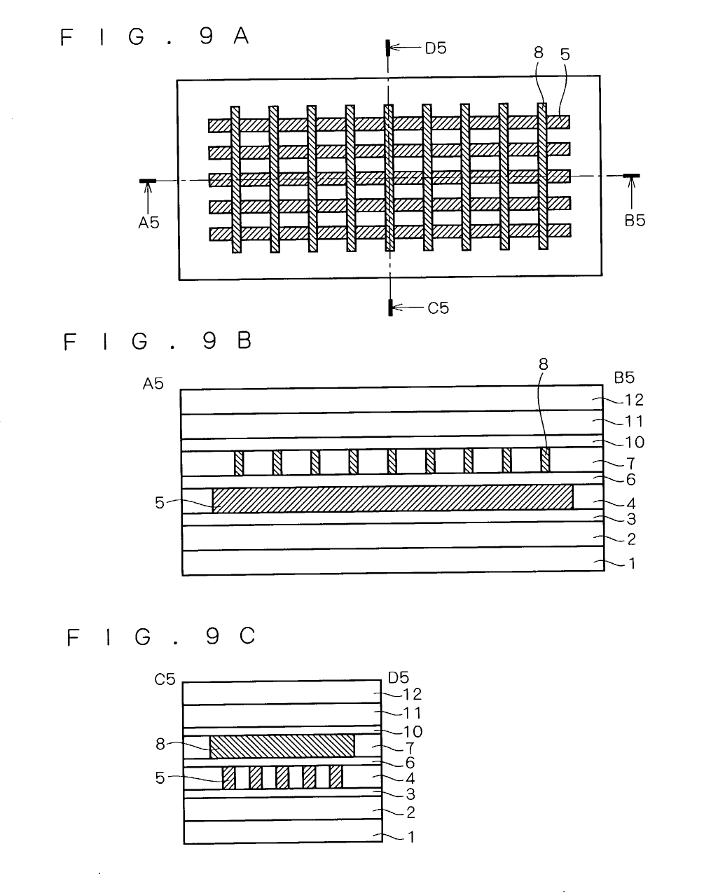

According to the third preferred embodiment of the present invention, the parallel lines of the underlying layers 5 follow different periodicity as that of the parallel openings of the alignment marks 8. FIGS. 14A through 14C illustrate an alignment mark structure according to the third preferred embodiment. FIG. 14A is a top plan view, FIG. 14B is a sectional view taken along a line I-J in FIG. 14A, and FIG. 14C is a sectional view taken along a line K-L in FIG. 14A. In FIGS. 14A through 14C, elements serving the same functions as those of the elements in FIGS. 1A through 1C are designated by the same reference numerals and the detailed description thereof is omitted here. The alignment mark structure according to the third preferred embodiment certainly achieves the same effect as obtained in the alignment mark structure according to the first preferred embodiment.

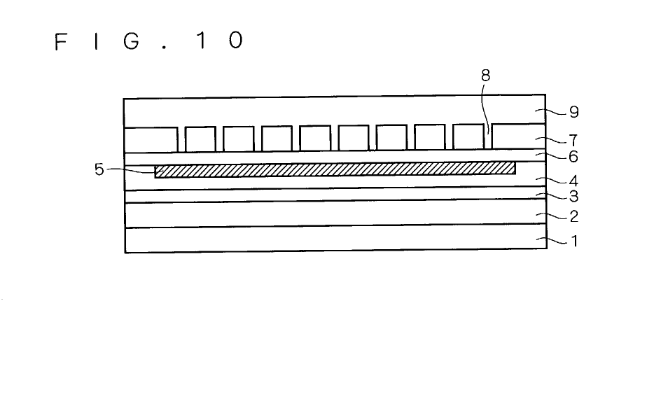

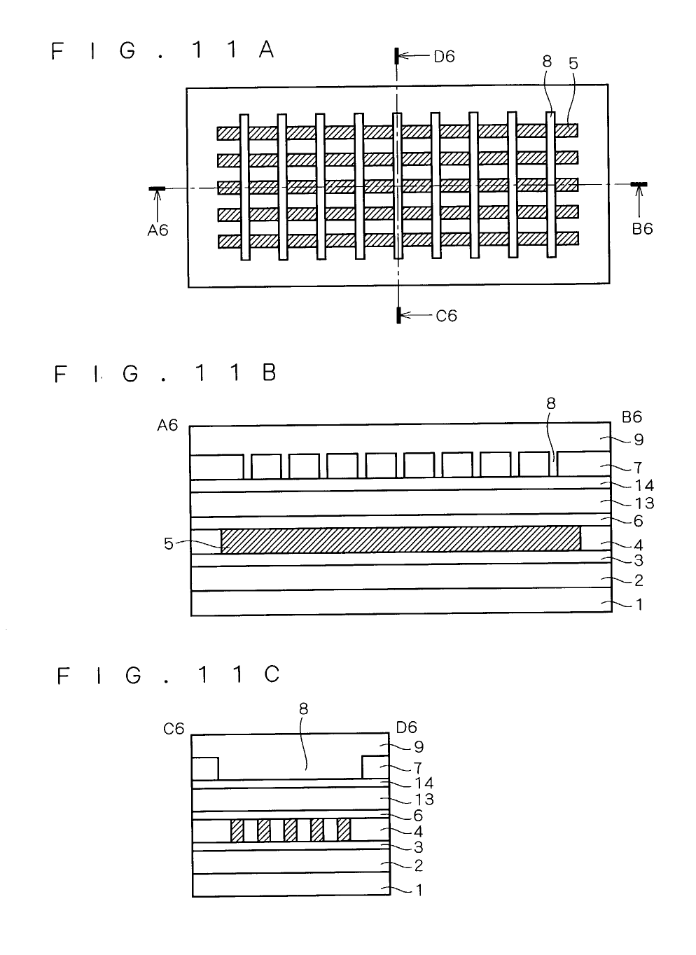

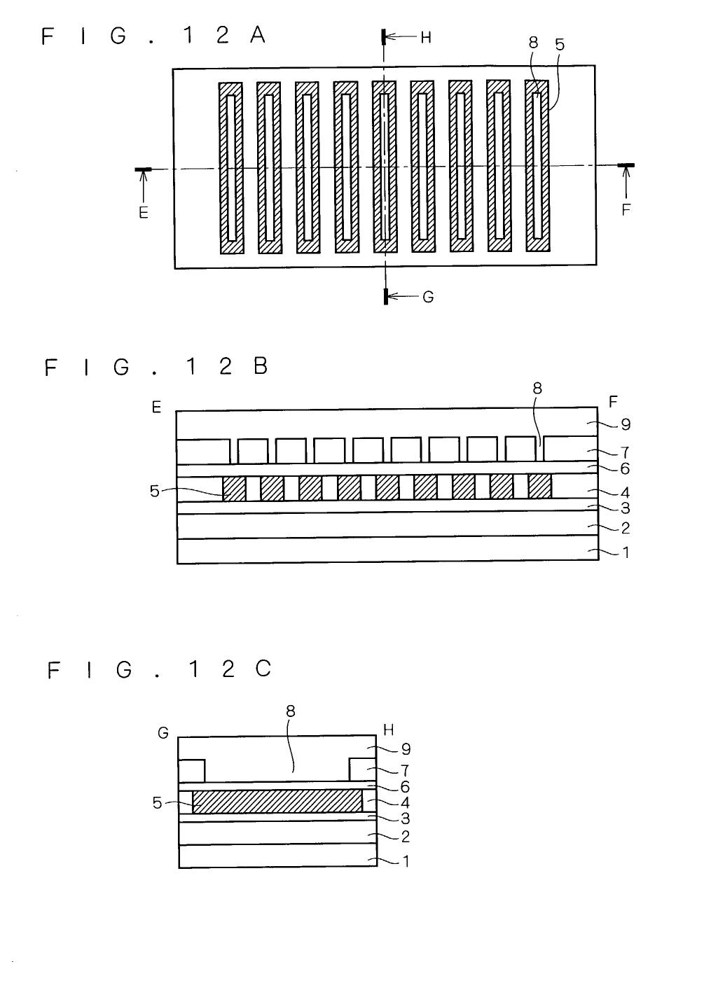

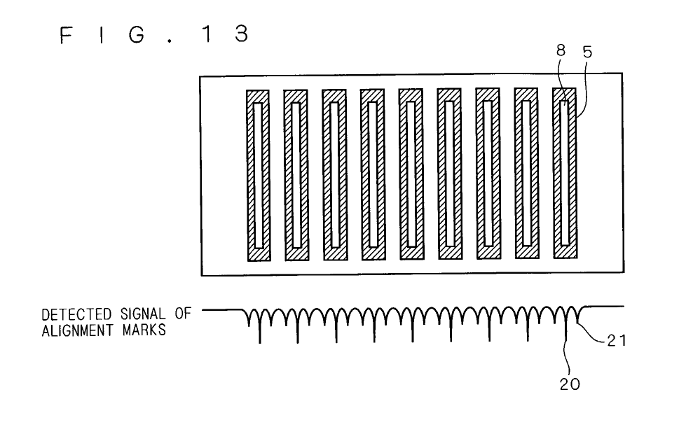

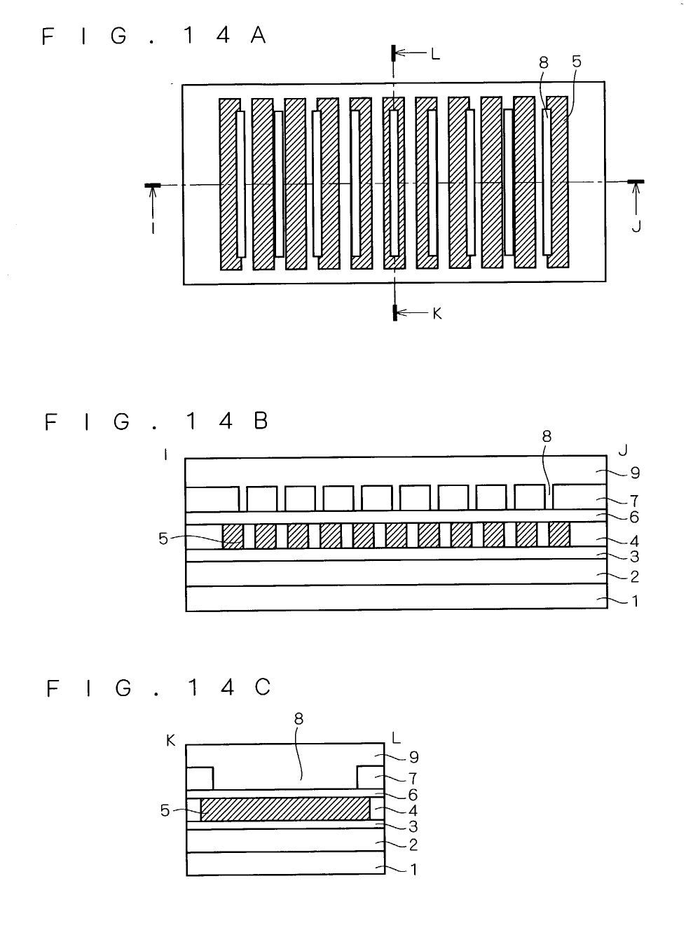

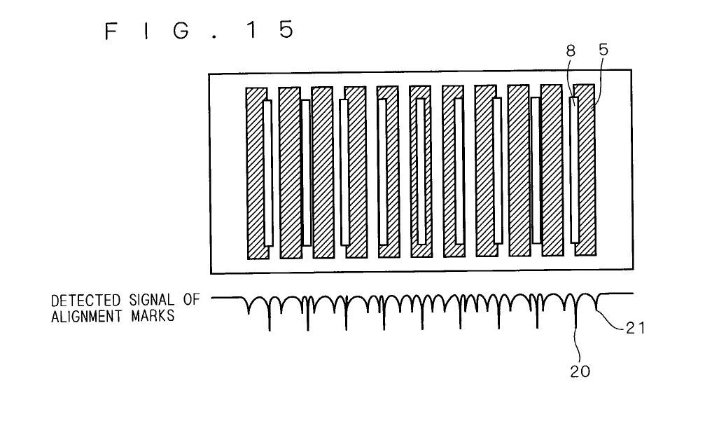

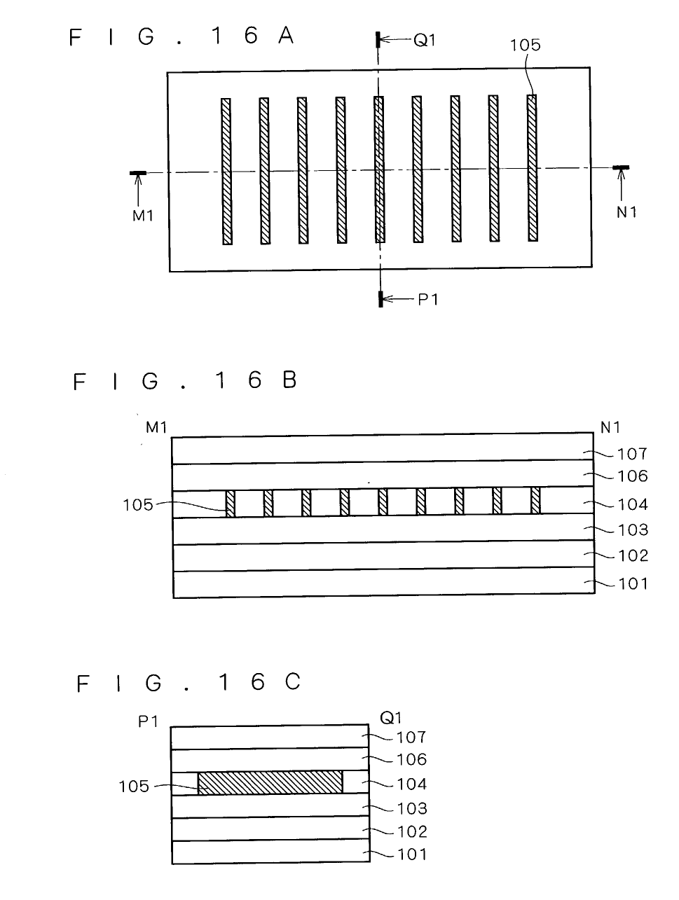

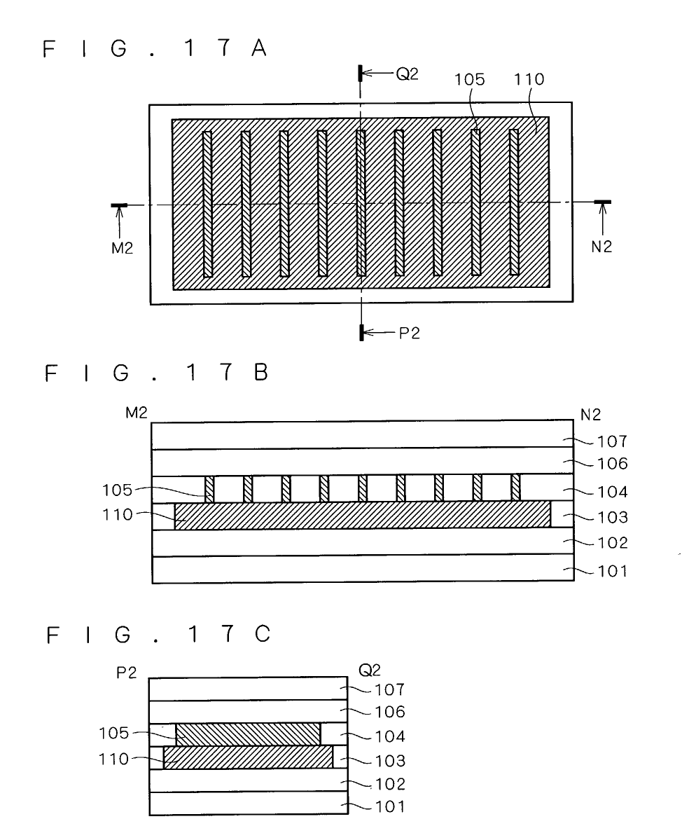

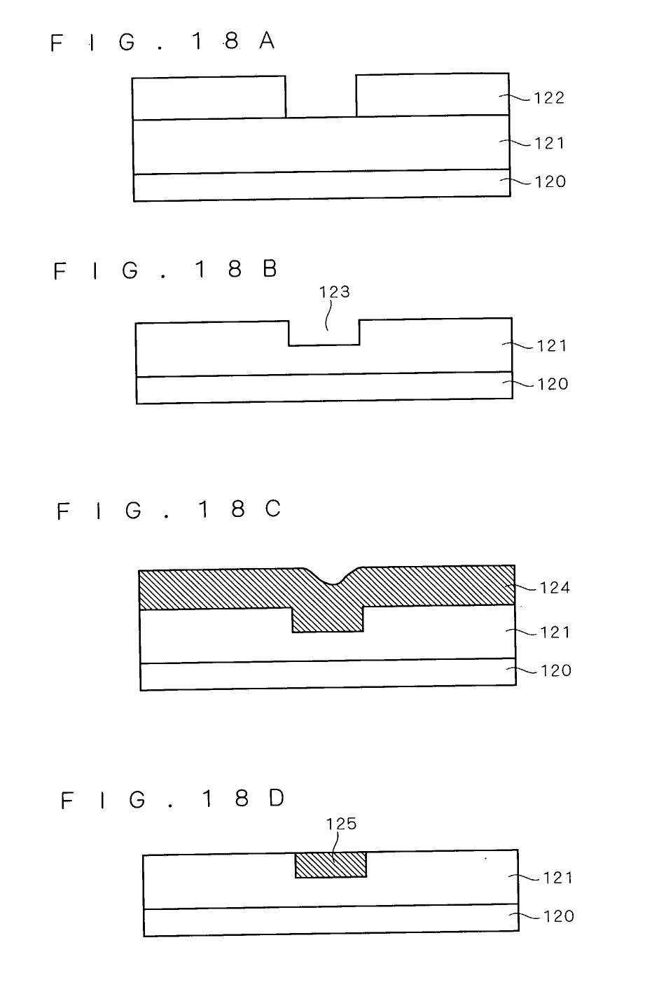

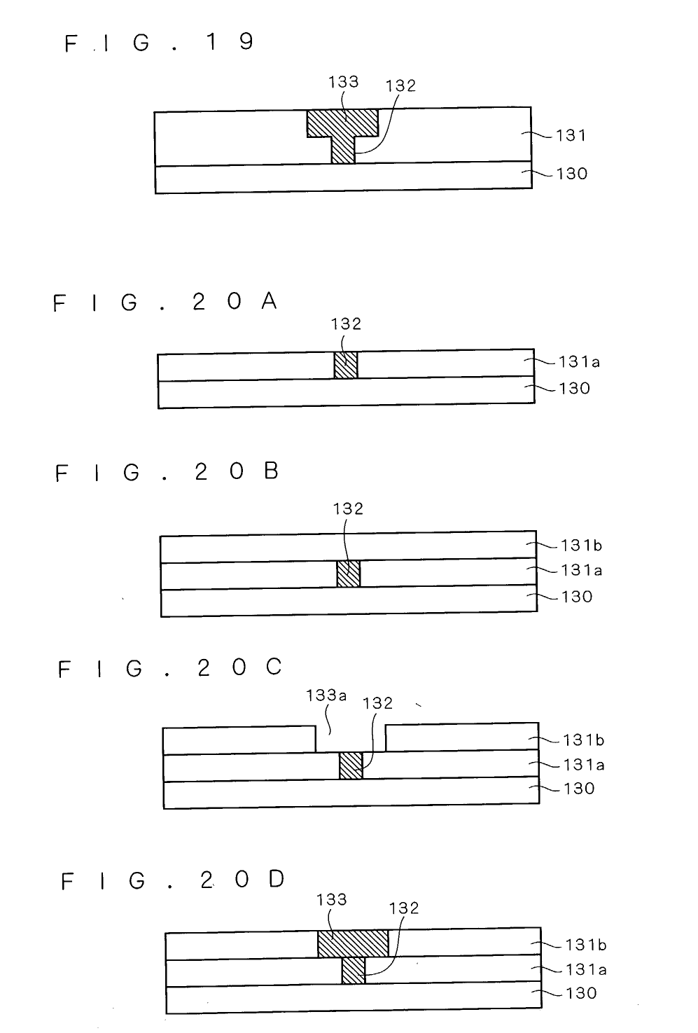

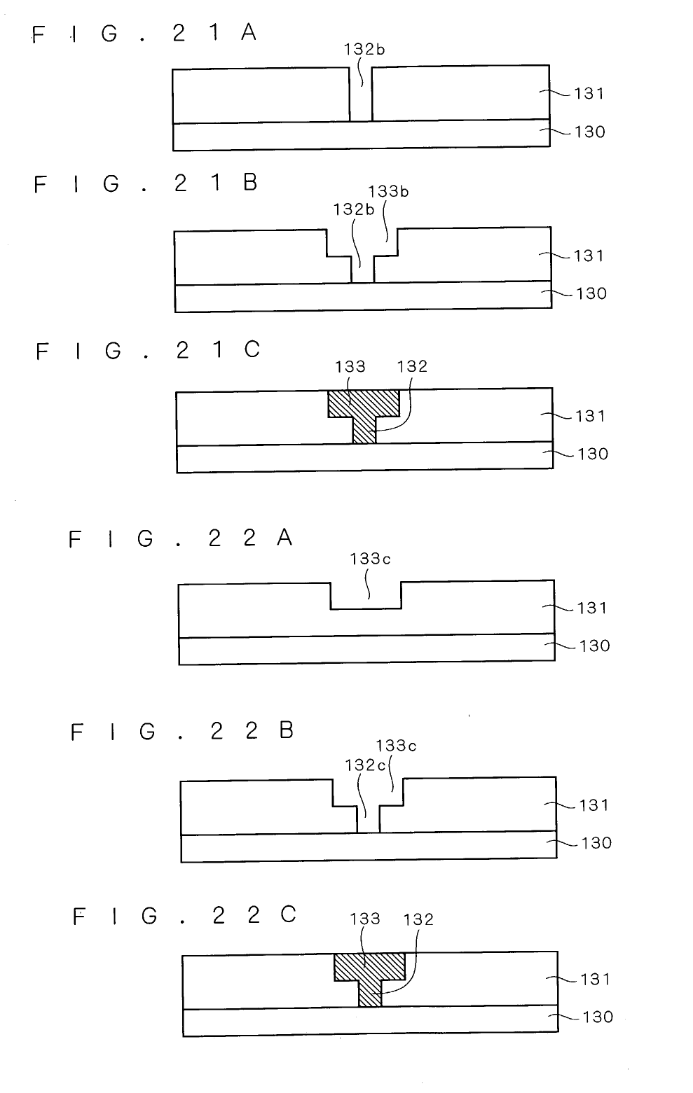

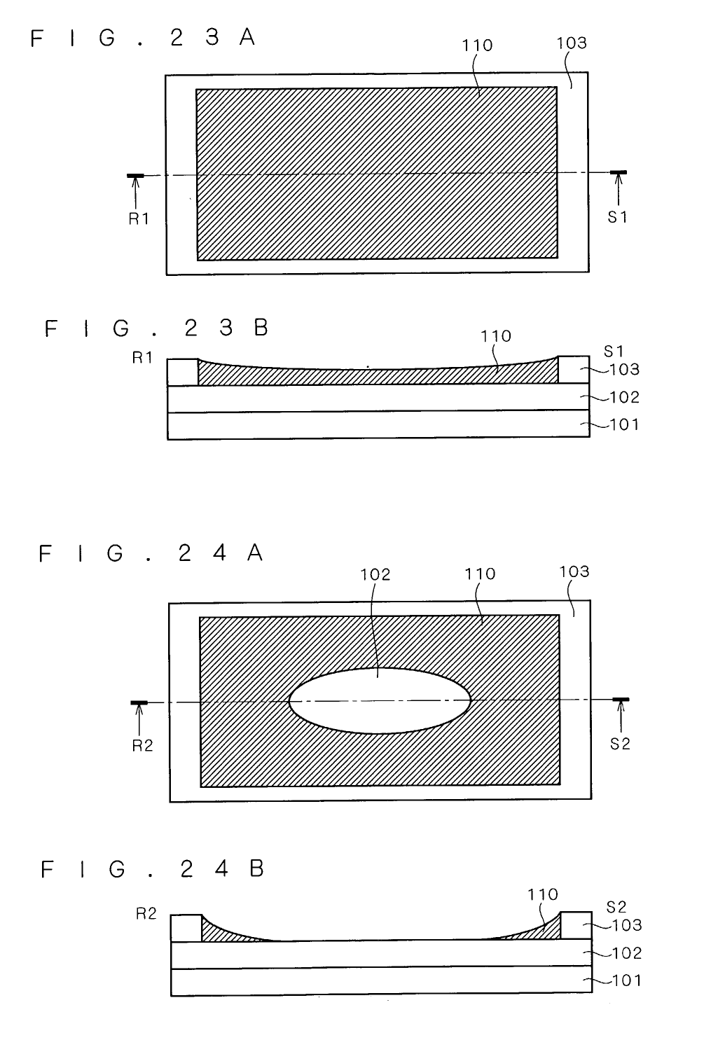

FIG. 15 shows a relation between a waveform of a signal detected by an alignment mark detector and positions of alignment marks in the process of reading alignment marks from the alignment mark structure illustrated in FIGS. 14A through 14C. Similar to the second preferred embodiment, the wave of the detected signal defined by the alignment marks has the peaks 20 at points of existence of the alignment marks 8. The wave further has the peaks 21 at edge portions of the underlying layers 5. Due to this, it is required to extract the peaks defined only by the alignment marks 8 through signal analysis. More particularly, the peaks defined by the alignment mark 8 and the edge portion of the underlying layer 5 are also detected in amplitude. When the peak has an amplitude higher than a predetermined threshold value, it is determined as the one defined by the alignment mark 8.

According to the third preferred embodiment, the underlying layers 5 and the alignment marks 8 are different in periodicity. As a result, in the waveform of the detected signal of the alignment marks, the peaks 20 at the alignment marks 8 and the peaks 21 at the edge portions of the underlying layers 5 show difference therebetween in periodicity. Periodicity of alignment marks is generally predetermined and therefore, peaks at the points of existence of the alignment marks 8 can be also distinguished by the periodicity thereof. In view of this, utilizing a combination of a determination made by periodicity of peaks and a determination made by difference in amplitude of peaks, the peaks defined only by the alignment marks 8 can be extracted with higher level of precision as compared with the second preferred embodiment.

According to the exemplary structure in FIGS. 14A through 14C, the alignment marks 8 are formed in the step of forming a hole through the hole first process. Alternatively, the third preferred embodiment is certainly applicable to the trench first process and the single damascene process.

In the figures utilized for the description so far, the exemplary alignment mark has been an FIA mark as one of those used in image recognition. However, the present invention is alternatively applicable to any other types of marks in image recognition such as an AGA mark. In this case, the same effect can be also achieved.

While the invention has been shown and described in detail, the foregoing description is in all aspects illustrative and not restrictive. It is therefore understood that numerous modifications and variations can be devised without departing from the scope of the invention.

What is claimed is:

1. An alignment mark structure having alignment marks and underlying layers, said underlying layers including metallic material and being arranged under said alignment marks, wherein
said underlying layers each form a line for defining a pattern,
said alignment mark structure further having a metal diffusion preventing and etching stopper layer directly on said underlying layers.

2. The alignment mark structure according to claim 1, wherein
said lines of said underlying layers defining said pattern are arranged in parallel.

3. The alignment mark structure according to claim 2, wherein
said alignment marks each form an opening for defining a pattern, said openings being arranged in parallel, and
each of said openings of said alignment marks and each of said lines of said underlying layers are orthogonal to each other in extending direction.

4. The alignment mark structure according to claim 2, wherein
said alignment marks each form an opening for defining a pattern, said openings being arranged in parallel, and
each of said openings of said alignment marks and each of said lines of said underlying layers are parallel with each other in extending direction.

5. The alignment mark structure according to claim 4, wherein
said pattern defined by said parallel openings of said alignment marks follows first periodicity,
said pattern defined by said parallel lines of said underlying layers follows second periodicity, and
said first periodicity and said second periodicity are different.
